(19) United States
(12) Patent Application Publication
(10) Pub. No.: US 2026/0101764 A1
(43) Pub. Date: Apr. 9, 2026

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Jeongwoo LEE, Suwon-si (KR); Kyunghwan NOH, Suwon-si (KR); Heecheol SHIN, Suwon-si (KR); Boryeon BAE, Suwon-si (KR); Sangjun LEE, Suwon-si (KR)

(73) Assignee: SAMSUNG ELECTRONICS CO., LTD., Suwon-si (KR)

(21) Appl. No.: 19/230,880

(22) Filed: Jun. 6, 2025

(30) Foreign Application Priority Data
Oct. 8, 2024 (KR) 10-2024-0136865

(51) Int. Cl. H01L 23/544; H01L 21/768; H01L 23/528; H01L 23/532

(52) U.S. Cl. CPC H10W 46/00; H10W 20/038; H10W 20/056; H10W 20/062; H10W 20/435; H10W 20/4441; H10W 20/4451; H10W 46/301; H10W 46/503

(57) ABSTRACT

Semiconductor devices and a method for manufacturing the semiconductor devices are provided. The method includes forming a plurality of bit-line structures on a chip region of a substrate, forming a first alignment key pattern on a scribe line region of the substrate, forming a first alignment key trench in at least a portion of the first alignment key pattern, forming a landing pad layer between the plurality of bit-line structures and on top surfaces of the plurality of bit-line structures, forming a gap-fill layer on the landing pad layer and in an unoccupied portion of the first alignment key trench and performing a planarization process on the gap-fill layer and the landing pad layer.

### CROSS-REFERENCE TO RELATED APPLICATION

This application is based on and claims priority under 35 U.S.C § 119 to Korean Patent Application No. 10-2024-0136865 filed on Oct. 8, 2024 in the Korean Intellectual Property Office, the disclosure of which is hereby incorporated by reference in its entirety.

### BACKGROUND

The disclosure relates to a semiconductor, and more particularly, to a semiconductor device and a method of fabricating the same.

Semiconductor devices have been increasingly required for high integration with the advanced development of the electronic industry. Semiconductor devices also have been increasingly requested for high speed with the advanced development of the electronic industry. Various studies have been conducted to meet the requirements of high integration and/or high speed in semiconductor devices. However, there is a problem of process margin reduction in an exposure process defining fine patterns, and as such, it is increasingly difficult to manufacture semiconductor devices with high efficiency.

In general, in order to manufacture (or fabricate) the semiconductor device, a predetermined material layer is formed on a semiconductor substrate (e.g., on a wafer), and then a photolithography process is performed to form a desired pattern. The photolithography process is carried out to form a photoresist layer on the semiconductor substrate on which the predetermined material layer is formed, to form a photoresist pattern by exposing and developing the photoresist layer using a mask, and to form a pattern by etching the predetermined material layer using the photoresist pattern. An exposure process may have an important role to determine accuracy of fabrication methods for the semiconductor device. When the exposure process is utilized to from a predetermined pattern on the semiconductor substrate, a photo-alignment key is employed to exactly align an exposure mask.

### SUMMARY

Some embodiments of the disclosure provide a semiconductor device with improved productivity and a method of fabricating the same.

One or more aspects of the disclosure is not limited to the mentioned above, and other aspects and/or objects which have not been mentioned above will be clearly understood to those skilled in the art from the following description.

According to an aspect of the disclosure, there is provided a method of manufacturing a semiconductor device, the method including: forming a plurality of bit-line structures on a chip region of a substrate; forming a first alignment key pattern on a scribe line region of the substrate; forming a first alignment key trench in at least a portion of the first alignment key pattern; forming a landing pad layer between the plurality of bit-line structures and on top surfaces of the plurality of bit-line structures; forming a gap-fill layer on the landing pad layer and in an unoccupied portion of the first alignment key trench; and performing a planarization process on the gap-fill layer and the landing pad layer.

The first alignment key pattern may include a first conductive pattern, a second conductive pattern on the first conductive pattern, and a capping pattern on the second conductive pattern, wherein the gap-fill layer may include a material that has an etch selectivity with respect to the capping pattern.

The gap-fill layer may include tungsten (W) or polycrystalline silicon (Si).

After the planarization process, a portion of the gap-fill layer may remain as a first gap-fill pattern in the first alignment key trench.

The unoccupied portion of the first alignment key trench may be filled with the first gap-fill pattern.

A top surface of the first gap-fill pattern may be located at a vertical level substantially same as or lower than a vertical level of a top surface of the first alignment key pattern.

When viewed in a direction parallel to a top surface of the substrate, a width of the first gap-fill pattern may decrease in a downward direction or is substantially constant.

A top surface of the first gap-fill pattern may have no step difference.

The planarization process may divide the landing pad layer into a plurality of landing pads and a first liner pattern, the plurality of landing pads provided between the plurality of bit-line structures and spaced apart from each other, and the first liner pattern provided in the first alignment key trench.

A top surface of the first gap-fill pattern may be located at a vertical level substantially same as or lower than a vertical level of a top surface of the first liner pattern.

The method may further include forming a plurality of second alignment key patterns on the scribe line region, wherein the landing pad layer is formed on a second alignment key trench between the plurality of second alignment key patterns, and wherein the gap-fill layer is formed in an unoccupied portion of the second alignment key trench.

After the planarization process, a portion of the gap-fill layer may remain as a second gap-fill pattern in the second alignment key trench.

A top surface of the second gap-fill pattern may be located at a vertical level substantially same as or lower than a vertical level of a top surface of each of the plurality of second alignment key patterns.

According to another aspect of the disclosure, there is provided a method of fabricating a semiconductor device, the method including: forming a plurality of bit-line structures on a chip region of a substrate; forming a first alignment key pattern on a scribe line region of the substrate; forming a first alignment key trench in at least a portion of the first alignment key pattern; forming a landing pad layer that fills between the plurality of bit-line structures and on top surfaces of the plurality of bit-line structures; forming a gap-fill layer on the landing pad layer and in the first alignment key trench; and performing a planarization process on the gap-fill layer and the landing pad layer, wherein, after the planarization process, a portion of the gap-fill layer remains in the first alignment key trench.

According to another aspect of the disclosure, there is provided a method of fabricating a semiconductor device, the method including: forming a plurality of bit-line structures on a chip region of a substrate; forming a first alignment key pattern on a scribe line region of the substrate; forming a plurality of storage node contacts between the plurality of bit-line structures; forming a first alignment key trench in at least a portion of the first alignment key pattern; forming a landing pad layer between the plurality of bit-line structures and on top surfaces of the plurality of bit-line structures; forming a gap-fill layer on the landing pad layer and in an unoccupied portion of the first alignment key trench; performing a planarization process on the gap-fill layer and the landing pad layer to divide the landing pad layer into a plurality of lower landing pads between the plurality of bit-line structures; forming a plurality of upper landing pads on the plurality of lower landing pads; and forming a plurality of data storage patterns on the plurality of upper landing pads.

According to another aspect of the disclosure, there is provided a semiconductor device, including: a substrate that includes a chip region and a scribe line region; a first alignment key pattern on the scribe line region; a first alignment key trench in at least a portion of the first alignment key pattern; a first liner pattern on the first alignment key trench; and a first gap-fill pattern in an unoccupied portion of the first alignment key trench.

The first gap-fill pattern may include tungsten (W) or polycrystalline silicon (Si).

A top surface of the first gap-fill pattern may be located at a vertical level substantially same as or lower than a vertical level of a top surface of the first alignment key pattern.

When viewed in a direction parallel to a top surface of the substrate, a width of the first gap-fill pattern may decrease in a downward direction or is substantially constant.

The semiconductor device may further include an upper dielectric layer on a top surface of the first alignment key pattern and a top surface of the first gap-fill pattern, wherein the first gap-fill pattern is between the first liner pattern and the upper dielectric layer, and wherein a contact area between the top surface of the first gap-fill pattern and the upper dielectric layer is substantially same as or greater than a contact area between a bottom surface of the first gap-fill pattern and the first liner pattern.

The first liner pattern may include: a first inner lateral surface in contact with a first lateral surface of the first gap-fill pattern; and a second inner lateral surface in contact with a second lateral surface of the first gap-fill pattern, wherein, when viewed in a direction parallel to a top surface of the substrate, a width of the first gap-fill pattern is substantially same as a distance between the first inner lateral surface and the second inner lateral surface of the first liner pattern.

The semiconductor device may further include a top surface of the first liner pattern has a step difference, and a top surface of the first gap-fill pattern does not have a step difference.

The semiconductor device may further include a plurality of second alignment key patterns on the scribe line region; a second alignment key trench between the plurality of second alignment key patterns; a second liner pattern on the second alignment key trench; and a second gap-fill pattern in an unoccupied portion of the second alignment key trench.

A top surface of the second gap-fill pattern is located at a vertical level substantially same as or lower than a vertical level of a top surface of each of the plurality of second alignment key patterns.

The first alignment key pattern may include a first conductive pattern, a second conductive pattern on the first conductive pattern, and a capping pattern on the second conductive pattern, and the first gap-fill pattern may include a material that has an etch selectivity with respect to the capping pattern.

### BRIEF DESCRIPTION OF DRAWINGS

FIG. 1 illustrates a plan view showing a semiconductor device according to some embodiments of the disclosure.

FIG. 2A illustrates a plan view partially showing a cell region of the semiconductor device depicted in FIG. 1.

FIG. 2B illustrates a plan view showing a first alignment key region of the semiconductor device depicted in FIG. 1.

FIG. 2C illustrates a plan view showing a second alignment key region of the semiconductor device depicted in FIG. 1.

FIG. 3A illustrates a cross-sectional view taken along line A-A′ of FIG. 2A.

FIG. 3B illustrates a cross-sectional view taken along line B-B′ of FIG. 2B.

FIG. 3C illustrates a cross-sectional view taken along line C-C′ of FIG. 2C.

FIGS. 4A to 4C, 5, 6A to 6C and 7A to 7C illustrate cross-sectional views showing a method of fabricating a semiconductor device according to some embodiments of the disclosure.

### DETAILED DESCRIPTION

Some embodiments of the disclosure will now be described in detail with reference to the accompanying drawings to aid in clearly explaining inventive concepts of the disclosure.

In the disclosure, each of the languages “A or B”, “at least one of A and B”, “at least one A or B”, “A, B, or C”, “at least one of A, B, and C”, and “at least one A, B, or C” may include one or any possible combination of elements listed in a corresponding one of the expressions mentioned above.

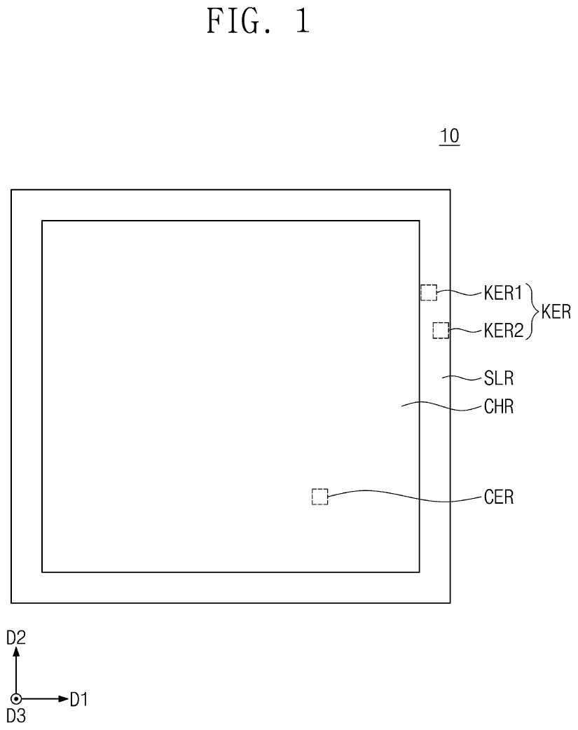

FIG. 1 illustrates a plan view showing a semiconductor device according to some embodiments of the disclosure.

Referring to FIG. 1, a semiconductor device 10 may include a chip region CHR and a scribe line region SLR. The chip region CHR may be one of a plurality of semiconductor chips formed on a semiconductor wafer. For example, the chip region CHR may include a semiconductor chip, among the plurality of semiconductor chips, formed on the semiconductor wafer. The scribe line region SLR may be a portion of a scribe line used for cutting a semiconductor wafer into a plurality of semiconductor chips after termination of fabrication process for the semiconductor chips. For example, the scribe line region SLR may include a portion of a scribe line used for cutting the semiconductor wafer into the plurality of semiconductor chips. The chip region CHR may include a cell region CER and a peripheral circuit region. The cell region CER may be a region on which memory cells are formed and the peripheral circuit region may be a region on which peripheral circuits are formed. The peripheral circuits may include, but is not limited to, circuits for controlling the memory cells. For example, the chip region CHR may include, but is not limited to, metal-oxide-semiconductor field-effect transistors (MOSFETs), a diode, and/or a resistor. For example, the scribe line region SLR may include, but is not limited to, a test device group and/or an alignment key region KER.

The alignment key region KER may include photo-alignment keys. The photo-alignment keys may be to as alignment keys. In an example case in which an exposure process is utilized to form a certain pattern on a semiconductor substrate, the alignment keys may be employed to exactly align an exposure mask. However, the disclosure is not limited thereto, and as such, the alignment keys may be used in another process. According to an embodiment, the shapes of the alignment keys may be identical or similar to the shapes of various components provided on the cell region CER. The alignment keys in the alignment key region KER may be classified into a local alignment key, a global alignment key, a registration alignment key, an overlay alignment key, and a measurement key. For example, the alignment keys may be classified in the different types of keys in accordance with their purpose.

In some of the drawings, the alignment key region KER is illustrated to reside on a localized portion, but the inventive concepts of the disclosure are not limited thereto. Accordingly to an embodiment, in the scribe line region SLR, the number and arrangement of the alignment key region KER may be variously changed by those skilled in the art. In addition, the position, placement, shape, and function of the alignment keys in the alignment key region KER may be diversely modified by those skilled in the art.

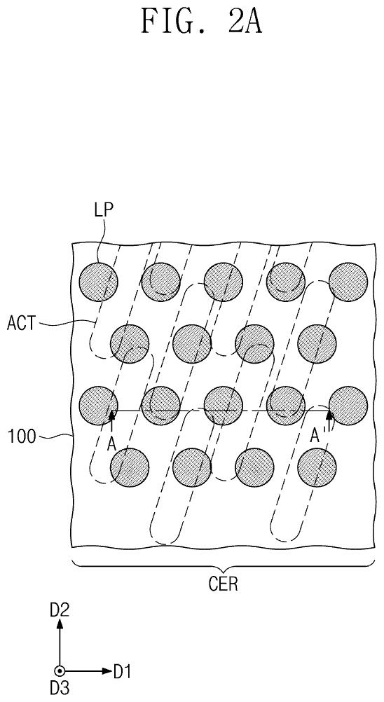

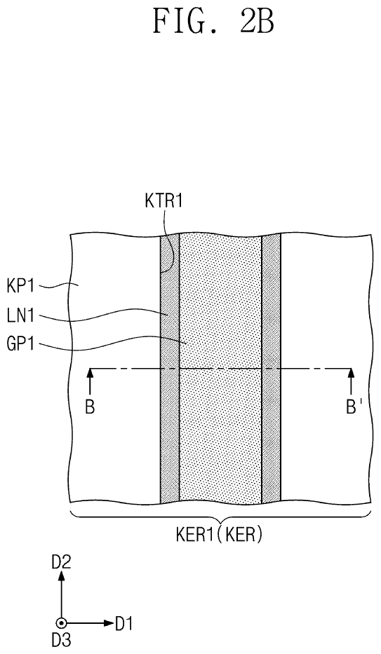

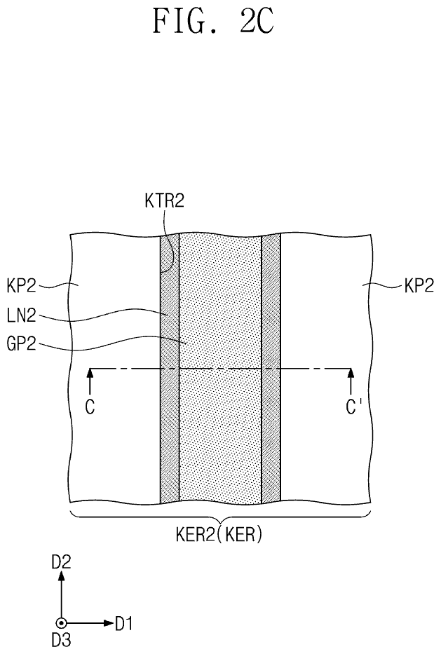

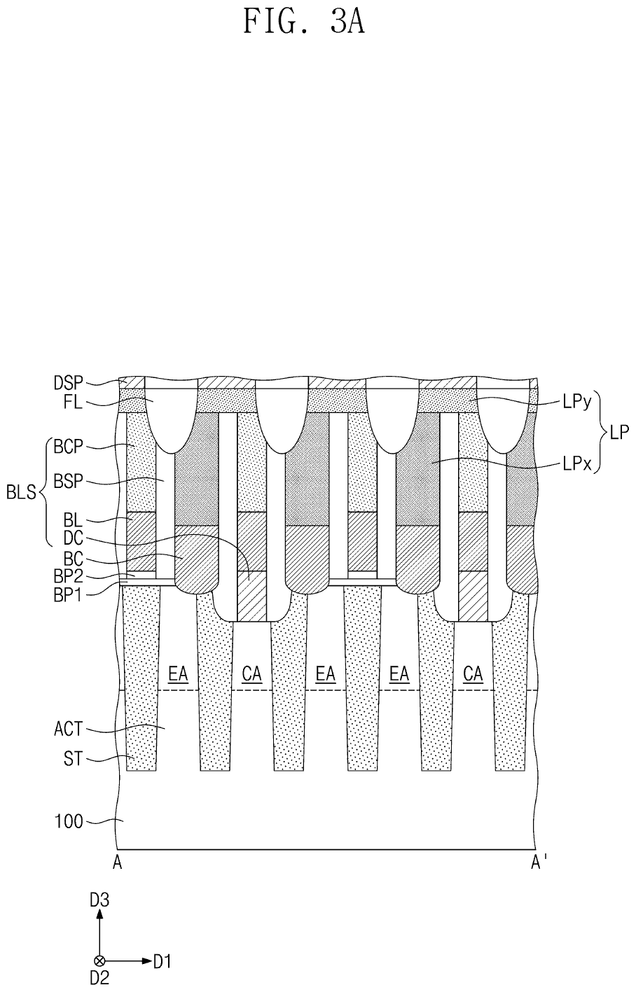

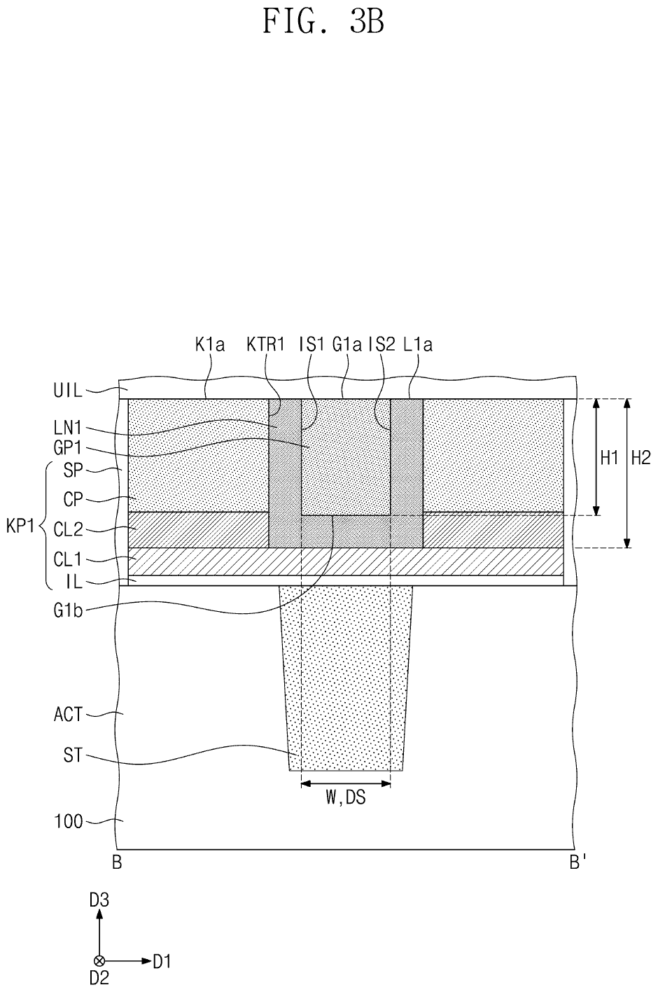

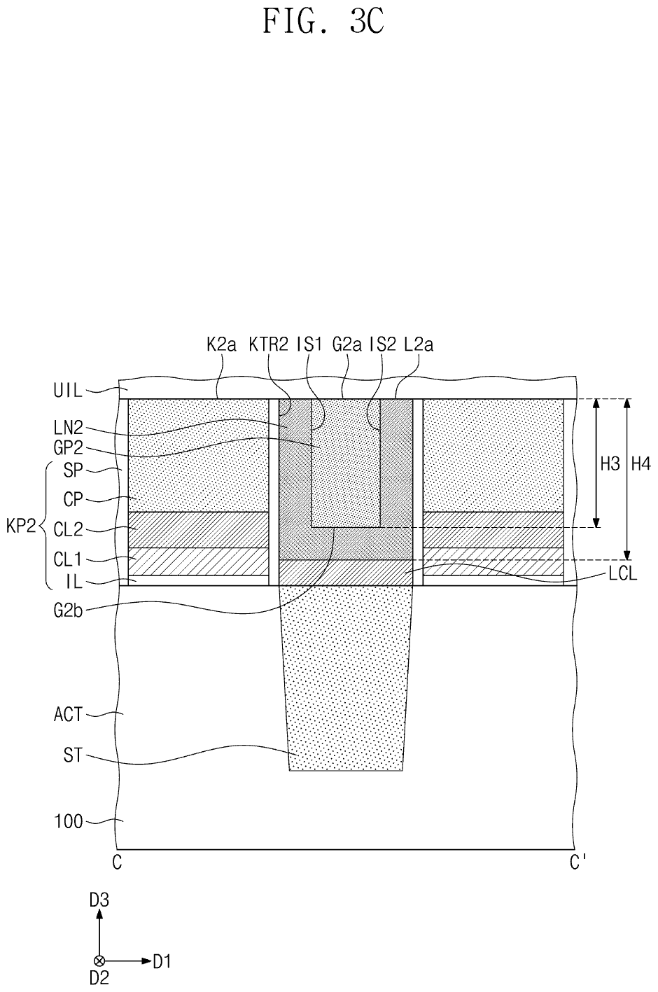

FIG. 2A illustrates a plan view partially showing a cell region of the semiconductor device depicted in FIG. 1. FIG. 2B illustrates a plan view showing a first alignment key region of the semiconductor device depicted in FIG. 1. FIG. 2C illustrates a plan view showing a second alignment key region of the semiconductor device depicted in FIG. 1. FIG. 3A illustrates a cross-sectional view taken along line A-A′ of FIG. 2A. FIG. 3B illustrates a cross-sectional view taken along line B-B′ of FIG. 2B. FIG. 3C illustrates a cross-sectional view taken along line C-C′ of FIG. 2C.

Referring to FIGS. 1, 2A, 2B, 2C, 3A, 3B, and 3C, a substrate 100 may be provided. The substrate 100 include a cell region CER and an alignment key region KER. The substrate 100 may be a semiconductor substrate, for example, a silicon substrate, a germanium substrate, or a silicon-germanium substrate. However, the disclosure is not limited thereto, and as such, the semiconductor substrate include another type of substrate.

According to an embodiment, a device isolation pattern ST may be provided on the substrate 100. For example, the device isolation pattern ST may define an active pattern ACT. The active pattern ACT may be provided in plural. For example, the active patterns ACT may include portions of the substrate 100 that are surrounded by the device isolation pattern ST. For convenience of description, unless otherwise specifically stated in this disclosure, the substrate 100 may be defined to indicate another portion other than the portions of the substrate 100 corresponding to the active patterns ACT.

The active patterns ACT may be spaced apart from each other in a first direction D1 and a second direction D2. The first direction D1 and the second direction D2 are parallel to a top surface of the substrate 100 and intersect each other. Each of the active patterns ACT may have an isolated island shape or an elongated bar shape. The active patterns ACT may protrude in a third direction D3 perpendicular to the top surface of the substrate 100.

The device isolation pattern ST may include a dielectric material. For example, the device isolation pattern ST may include, but is not limited to, silicon oxide (SiO₂) and silicon nitride (SiN). The device isolation pattern ST may be a single layer formed of one material or a multiple layer formed of two or more materials.

The active pattern ACT may include edge parts EA spaced apart from each other and a central part CA between the edge parts EA. The edge parts EA and the central part CA may be doped with impurities. For example, the edge parts EA and the central part CA may be doped with n-type impurities or p-type impurities.

According to an embodiment, on the cell region CER, word lines may run across the active patterns ACT and the device isolation pattern ST. The word lines may each extend along the first direction D1 and may be spaced apart from each other along the second direction D2.

According to an embodiment, on the cell region CER, a first buffer pattern BP1 may be provided on the active patterns ACT and the device isolation pattern ST. For example, the first buffer pattern BP1 may cover the active patterns ACT and the device isolation pattern ST. For example, the first buffer pattern BP1 may include, but is not limited to, silicon oxide (SiO₂), silicon nitride (SiN), and silicon oxynitride (SiON).

According to an embodiment, bit lines BL may be provided on the central parts CA of the active patterns ACT on the cell region CER. The bit lines BL may each extend along the second direction D2 and may be spaced apart from each other in the first direction D1. Each of the bit lines BL may be connected to the central part CA of the active pattern ACT through a bit-line contact DC which will be discussed below. The bit lines BL may include, for example, a conductive material.

According to an embodiment, a second buffer pattern BP2 may be between the bit lines BL and the first buffer pattern BP1. For example, the second buffer pattern BP2 may be interposed between the bit lines BL and the first buffer pattern BP1. For example, the second buffer pattern BP2 may include polysilicon.

According to an embodiment, bit-line contacts DC may be between the bit lines BL and central parts CA of the active patterns ACT on the cell region CER. For example, the bit-line contacts DC may be interposed between the bit lines BL and central parts CA. For example, the bit-line contact DC may include, but is not limited to, impurity-doped polysilicon, impurity-undoped polysilicon, and conductive materials such as metal.

For example, a component may be separately interposed between the bit lines BL and the bit-line contacts DC. The component may include, but is not limited to, metal silicide and metal nitride.

According to an embodiment, a bit-line capping pattern BCP may extend along the second direction D2 on a top surface of each of the bit lines BL. The bit-line capping patterns BCP may be provided adjacent to each other in the first direction D1. For example, the bit-line capping patterns BCP may neighbor each other in the first direction D1. The bit-line capping pattern BCP may be formed of a single layer or a plurality of layers. The bit-line capping pattern BCP may include a first capping pattern, a second capping pattern, and a third capping pattern that are sequentially stacked. For example, each of the first to third capping patterns may include silicon nitride (SiN). However, the disclosure is not limited to three capping patterns.

According to an embodiment, a bit-line spacer BSP may be provided on a lateral surface of the bit-line contact DC, a lateral surface of the bit line BL, and a lateral surface of the bit-line capping pattern BCP. For example, the bit-line spacer BSP may include, but is not limited to, silicon oxide (SiO₂), silicon nitride (SiN), silicon carbonitride (SiOC), and silicon oxycarbonitride (SiOCN). The bit-line spacer BSP may be formed of a single layer or a plurality of layers.

The bit line BL, the bit-line contact DC, the bit-line capping pattern BCP, and the bit-line spacer BSP may constitute a bit-line structure BLS.

According to an embodiment, a storage node contact BC may be provided between the bit lines BL that is adjacent to each other in the first direction D1. The storage node contacts BC may be spaced apart from each other in the first and second directions D1 and D2. Each of the storage node contacts BC may be connected to the edge part EA of the active pattern ACT on the cell region CER. For example, the storage node contact BC may include, but is not limited to, impurity-doped polysilicon, impurity-undoped polysilicon, and a conductive material such as metal.

According to an embodiment, a landing pad LP may be provided on the storage node contact BC. The landing pad LP may be connected through the storage node contact BC to the edge part EA of the active pattern ACT on the cell region CER that correspond to the landing pad LP.

The landing pad LP may include a lower landing pad LPx and an upper landing pad LPy that are sequentially provided on the storage node contact BC. Each of the lower and upper landing pads LPx and LPy may include a conductive material. For example, the lower landing pad LPx may include, but is not limited to, titanium nitride (TiN), and the upper landing pad LPy may include, but is not limited to, tungsten (W).

According to an embodiment, a filling pattern FL may surround the upper landing pads LPy. The filling layer FL may be interposed between and separate from each other the upper landing pads LPy that is adjacent to each other. The filling layer FL may include a dielectric material. For example, the filling layer FL may include an air gap.

According to an embodiment, a data storage pattern DSP may be provided on the upper landing pads LPy. For example, the data storage pattern DSP may include, but is not limited a capacitor including a bottom electrode, a dielectric layer, and a top electrode. In this case, a semiconductor device according to an embodiment of the disclosure may be a dynamic random access memory (DRAM). In another example, the data storage pattern DSP may include a magnetic tunnel junction pattern. In this case, a semiconductor device according to an embodiment of the disclosure may be a magnetic random access memory (MRAM). In yet another example, the data storage pattern DSP may include a phase change material or a variable resistance material. In this case, a semiconductor device according to an embodiment of the disclosure may be a phase change random access memory (PRAM) or a resistive random access memory (ReRAM). This is, however, merely exemplary, and the inventive concepts of the disclosure are not limited thereto. The data storage pattern DSP may include various structures and/or materials capable of storing data.

Referring to FIGS. 2B and 3B, according to an embodiment, a first alignment key pattern KP1 may be provided on the active pattern ACT of a first alignment key region KER1. The first alignment key pattern KP1 may correspond to the photo-alignment key discussed with reference to FIG. 1. In FIG. 3B, it is illustrated that a single first alignment key pattern KP1 is provided on the active pattern ACT of the first alignment key region KER1, but the inventive concepts of the disclosure are not limited thereto. In addition, the first alignment key pattern KP1 may extend in the second direction D2, but the inventive concepts of the disclosure are not limited thereto. The first alignment key pattern KP1 may extend in one direction parallel to the top surface of the substrate 100. In an example case in which the first alignment key pattern KP1 is provided in plural (e.g., a plurality of first alignment key pattern KP1), the plurality of first alignment key patterns KP1 may have their extending directions that are different from each other.

The first alignment key pattern KP1 may include a dielectric pattern IL, a first conductive pattern CL1, a second conductive pattern CL2, and a capping pattern CP. The dielectric pattern IL, the first conductive pattern CL1, the second conductive pattern CL2, and the capping pattern CP may be sequentially stacked on the active pattern ACT of the first alignment key region KER1. The first alignment key pattern KP1 may also include spacer SP provided on a lateral (or a side) surface of each of the dielectric pattern IL, the first conductive pattern CL1, the second conductive pattern CL2, and the capping pattern CP. For example, the spacer SP may cover a lateral surface of each of the dielectric pattern IL, the first conductive pattern CL1, the second conductive pattern CL2, and the capping pattern CP.

For example, the dielectric pattern IL may include, but is not limited to, silicon oxide, silicon oxynitride, and high-k dielectric having a dielectric constant greater than that of silicon oxide. The high-k dielectric may include, but is not limited to, dielectric metal oxide such as hafnium oxide or aluminum oxide.

The first conductive pattern CL1 may include a conductive material. For example, the first conductive pattern CL1 may include a same material as the material of the bit-line contact DC. The second conductive pattern CL2 may include a conductive material. For example, the conductive material may be a metallic material. For example, the second conductive pattern CL2 may include a same material as the material of the bit line BL. According to an embodiment, a component, which includes metal silicide or metal nitride, may be separately interposed between the first conductive pattern CL1 and the second conductive pattern CL2.

The capping pattern CP may include a dielectric material. For example, the capping pattern CP may include the same number of layers as the bit-line capping pattern BCP. For example, the capping pattern CP may include the same material as the layers of the bit-line capping pattern BCP.

The spacer SP may include a dielectric material. For example, the spacer SP may include the same number of layers as the bit-line spacer BSP. For example, the spacer SP may include the same material as the layers of the bit-line spacer BSP.

According to an embodiment, a first alignment key trench KTR1 may be provide in the first alignment key pattern KP1. For example, the first alignment key trench KTR1 may penetrate at least a portion of the first alignment key pattern KP1. In some drawings, the first alignment key trench KTR1 is illustrated to extend in the second direction D2, but the inventive concepts of the disclosure are not limited thereto. The first alignment key trench KTR1 may extend along an extending direction of the first alignment key pattern KP1. For example, the first alignment key trench KTR1 may extend from an upper surface of the first alignment key pattern KP1 towards the substrate 100. For example, the first alignment key trench KTR1 may be provided on a top surface of the first conductive pattern CL1. The first alignment key trench KTR1 may separate the capping pattern CP into a pair of capping patterns CP that are spaced apart from each other in a direction (e.g., the first direction D1) that intersects an extending direction (e.g., the second direction D2) of the first alignment key trench KTR1. For example, the first alignment key trench KTR1 may vertically overlap the device isolation pattern ST.

According to an embodiment, a first liner pattern LN1 may be provided in the first alignment key trench KTR1. For example, the first liner pattern LN1 may be provided within the first alignment key trench KTR1. For example, the first liner pattern LN1 may be configured to conform to the first alignment key trench KTR1. For example, the first liner pattern LN1 may conformally cover the first alignment key trench KTR1. For example, the phrase “a certain component conformally covers a trench” may mean that a thickness in a horizontal direction of the certain component on an inner lateral surface of the trench is substantially the same as a thickness in a vertical direction of the certain component on an inner bottom surface of the trench. A top surface L1a of the first liner pattern LN1 may be located at a vertical level substantially the same as or lower than that of a top surface K1a of the first alignment key pattern KP1 (or a top surface of the capping pattern CP). For example, the first liner pattern LN1 may include a conductive material. For example, the first liner pattern LN1 may include a same material as the material of the lower landing pad LPx.

According to an embodiment, a first gap-fill pattern GP1 may be provided in the first alignment key trench KTR1. For example, the first gap-fill pattern GP1 may be provided within the first alignment key trench KTR1. The first gap-fill pattern GP1 may be provided on the first liner pattern LN1. The first gap-fill pattern GP1 may fill an unoccupied portion of the first alignment key trench KTR1. In this description, the phrase “material A fills an unoccupied portion of a trench” may mean that material B fills a portion of the trench and material A fills another portion of the trench, so that an inner portion of the trench is entirely filled with materials A and B. Material B may be a single component or a plurality of components. A seam may exist between (or within) material A or material B filling the trench.

A step difference may be present on the top surface L1a of the first liner pattern LN1, and no step difference may be present on a top surface G1a of the first gap-fill pattern GP1. As the first gap-fill pattern GP1 fills an unoccupied portion of the first alignment key trench KTR1, even though the step difference is formed on the top surface L1a of the first liner pattern LN1, no step difference may be formed within the first alignment key trench KTR1.

The first gap-fill pattern GP1 may include a material that has an etch selectivity with respect to the capping pattern CP. For example, the first gap-fill pattern GP1 may include, but is not limited to, tungsten (W) and polycrystalline silicon (Si). In some drawings, the first gap-fill pattern GP1 is illustrated as a single component, but the inventive concepts of the disclosure are not limited thereto.

The first gap-fill pattern GP1 may fill an unoccupied portion of the first alignment key trench KTR1. For example, the top surface G1a of the first gap-fill pattern GP1 may be located at a vertical level lower than or substantially the same as that of the top surface L1a of the first liner pattern LN1. The top surface G1a of the first gap-fill pattern GP1 may be located at a vertical level substantially the same as or lower than that of the top surface K1a of the first alignment key pattern KP1 (or the top surface of the capping pattern CP). A contact area between the top surface G1a of the first gap-fill pattern GP1 and an upper dielectric layer UIL may be substantially the same as or greater than a contact area between a bottom surface G1b of the first gap-fill pattern GP1 and the first liner pattern LN1. When viewed in the third direction D3, a width W in the first direction D1 of the first gap-fill pattern GP1 may be substantially the same as a distance DS between a first inner lateral surface IS1 and a second inner lateral surface IS2 of the first liner pattern LN1. The first inner lateral surface IS1 of the first liner pattern LN1 may be in contact with one lateral surface of the first gap-fill pattern GP1, and the second inner lateral surface IS2 of the first liner pattern LN1 may be in contact with another lateral surface of the first gap-fill pattern GP1.

When viewed in the first direction D1, a width of the top surface G1a of the first gap-fill pattern GP1 may be substantially the same as or greater than a width of the bottom surface G1b of the first gap-fill pattern GP1. The width W of the first gap-fill pattern GP1 may decrease in a downward direction or may be substantially constant. A height H1 of the first gap-fill pattern GP1 may be less than a height H2 of the first liner pattern LN1.

Referring to FIGS. 2C and 3C, according to an embodiment, a second alignment key pattern KP2 may be provided on the active pattern ACT of a second alignment key region KER2. The second alignment key pattern KP2 may correspond to the photo-alignment key discussed with reference to FIG. 1. According to an embodiment illustrated in FIGS. 2C and 3C, a pair of second alignment key patterns KP2 are provided on the active pattern ACT of the second alignment key region KER2, but the inventive concepts of the disclosure are not limited thereto. In addition, the second alignment key pattern KP2 may extend in the second direction D2, but the inventive concepts of the disclosure are not limited thereto. The second alignment key pattern KP2 may extend in one direction parallel to the top surface of the substrate 100. In some drawings, the second alignment key pattern KP2 is illustrated to extend along the same direction as that of the first alignment key pattern KP1, but the inventive concepts of the disclosure are not limited thereto. In an example case in which the second alignment key pattern KP2 is provided in plural, the plurality of second alignment key patterns KP2 may have their extending directions different from each other.

According to an embodiment, a second alignment key trench KTR2 may be provided between the second alignment key patterns KP2. For example, the second alignment key trench KTR2 may be provided between a pair of adjacent second alignment key patterns KP2. In some drawings, the second alignment key trench KTR2 is illustrated to extend in the second direction D2, but the inventive concepts of the disclosure are not limited thereto. The second alignment key trench KTR2 may extend along an extending direction of the second alignment key pattern KP2. The second alignment key trench KTR2 may separate the second alignment key patterns KP2 from each other in the first direction D1.

The second alignment key pattern KP2 may include a dielectric pattern IL, a first conductive pattern CL1, a second conductive pattern CL2, and a capping pattern CP. The dielectric pattern IL, the first conductive pattern CL1, the second conductive pattern CL2, and the capping pattern CP may be sequentially stacked on the active pattern ACT of the second alignment key region KER2. According to an embodiment, the second alignment key pattern KP2 may also include spacer SP provided on a lateral surface of each of the dielectric pattern IL, the first conductive pattern CL1, the second conductive pattern CL2, and the capping pattern CP. For example, the spacer SP may cover a lateral surface of each of the dielectric pattern IL, the first conductive pattern CL1, the second conductive pattern CL2, and the capping pattern CP. The stacked components of the second alignment key pattern KP2 may be the same as or similar to those of the first alignment key pattern KP1.

According to an embodiment, a lower conductive pattern LCL may be provided in a lower portion of the second alignment key trench KTR2. The lower conductive pattern LCL may include a conductive material. For example, the lower conductive pattern LCL may include a same material as the material of the storage node contact BC.

According to an embodiment, second liner pattern LN2 may be provided in the second alignment key trench KTR2. For example, the second liner pattern LN2 may be provided within the second alignment key trench KTR2. The second liner pattern LN2 may be configured to conform to the second alignment key trench KTR2. For example, the second liner pattern LN2 may conformally cover the second alignment key trench KTR2. The second liner pattern LN2 may be provided on a top surface of the lower conductive pattern LCL. A top surface L2a of the second liner pattern LN2 may be located at a vertical level substantially the same as or lower than that of a top surface K2a of the second alignment key pattern KP2 (or a top surface of the capping pattern CP). For example, the second liner pattern LN2 may include a conductive material. For example, the second liner pattern LN2 may include a same material as the material of the lower landing pad LPx and that of the first liner pattern LN1.

According to an embodiment, a second gap-fill pattern GP2 may be provided in the second alignment key trench KTR2. For example, the second gap-fill pattern GP2 may be provided within the second alignment key trench KTR2. The second gap-fill pattern GP2 may be provided on the second liner pattern LN2. The second gap-fill pattern GP2 may fill an unoccupied portion of the second alignment key trench KTR2. As the second gap-fill pattern GP2 fills an unoccupied portion of the second alignment key trench KTR2, even though a step difference is formed on the top surface L2a of the second liner pattern LN2, no step difference may be formed within the second alignment key trench KTR2. For example, the second gap-fill pattern GP2 may include a same material as the material of the first gap-fill pattern GP1.

According to an embodiment, a relationship between the second gap-fill pattern GP2 and surrounding components may be the same as or similar to that between the first gap-fill pattern GP1 and surrounding components. For example, a top surface G2a of the second gap-fill pattern GP2 may be located at substantially the same as or lower than that of the top surface L2a of the second liner pattern LN2 and that of the top surface K2a of the second alignment key pattern KP2. A contact area between the top surface G2a of the second gap-fill pattern GP2 and an upper dielectric layer UIL may be substantially the same as or greater than a contact area between a bottom surface G2b of the second gap-fill pattern GP2 and the second liner pattern LN2. A height H3 of the second gap-fill pattern GP2 may be less than a height H4 of the second liner pattern LN2.

According to an embodiment, an upper dielectric layer UIL may be provided on the top surface K1a of the first alignment key pattern KP1 and the top surface K2a of the second alignment key pattern KP2. For example, the upper dielectric layer UIL may include a single layer or a plurality of layers.

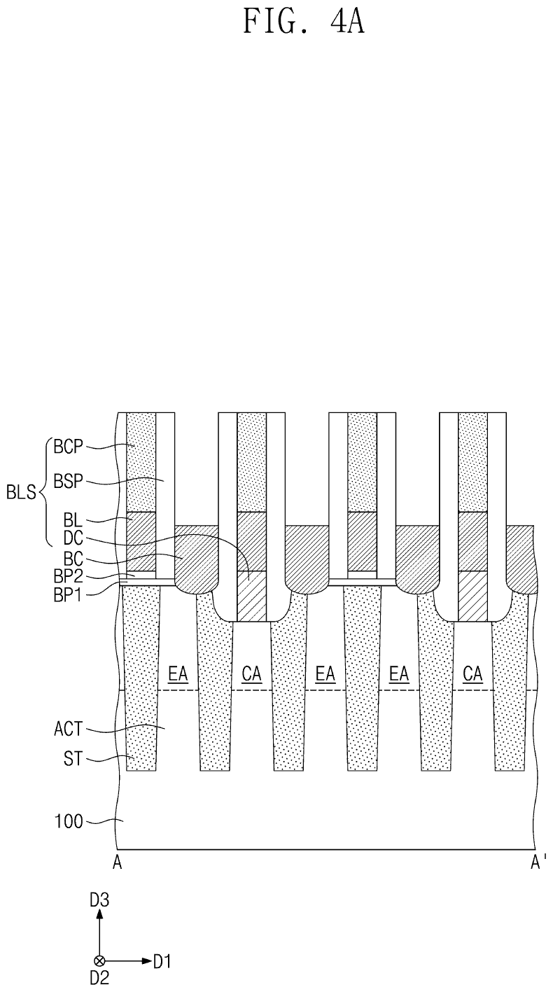

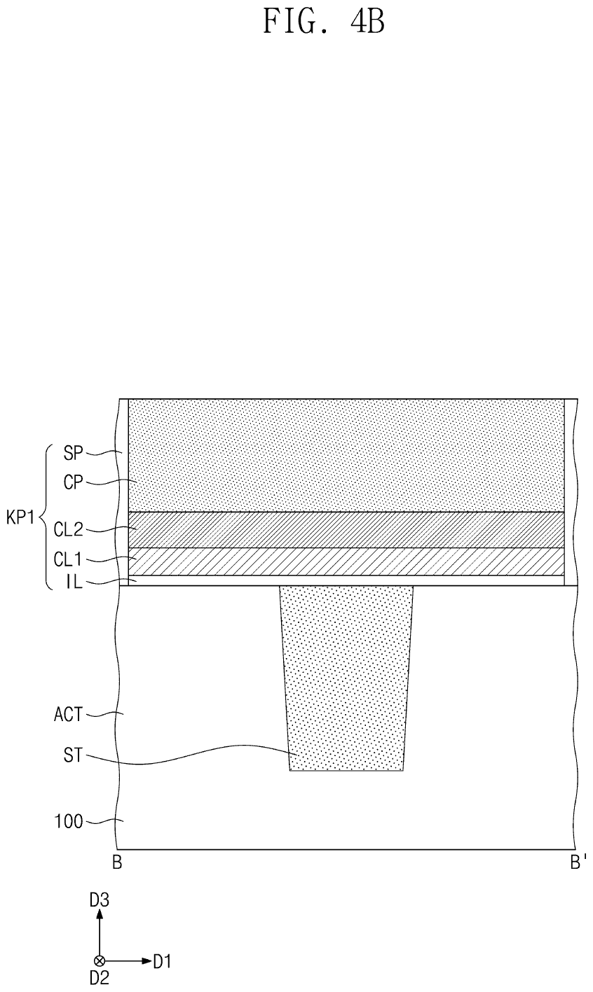

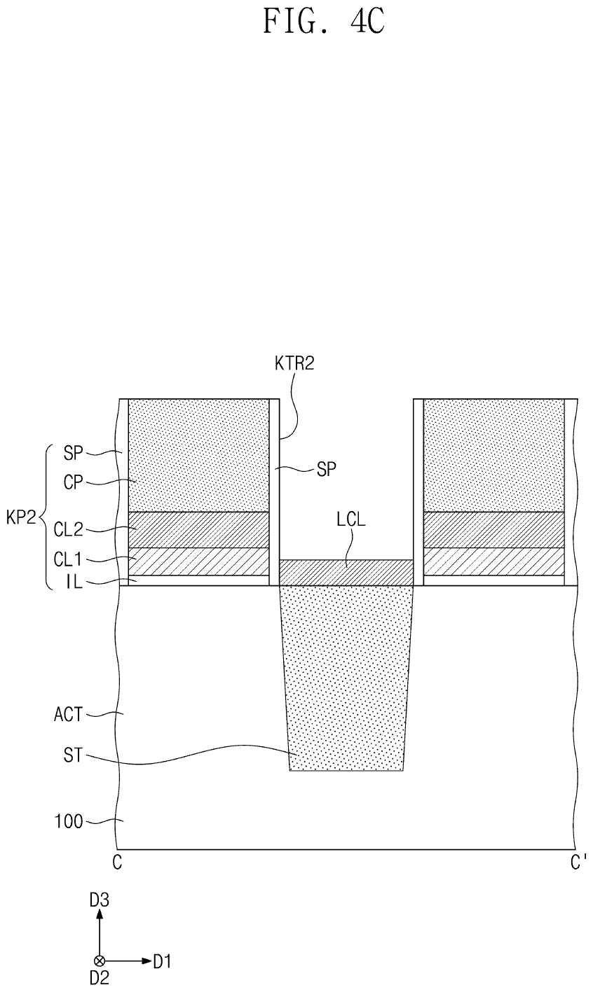

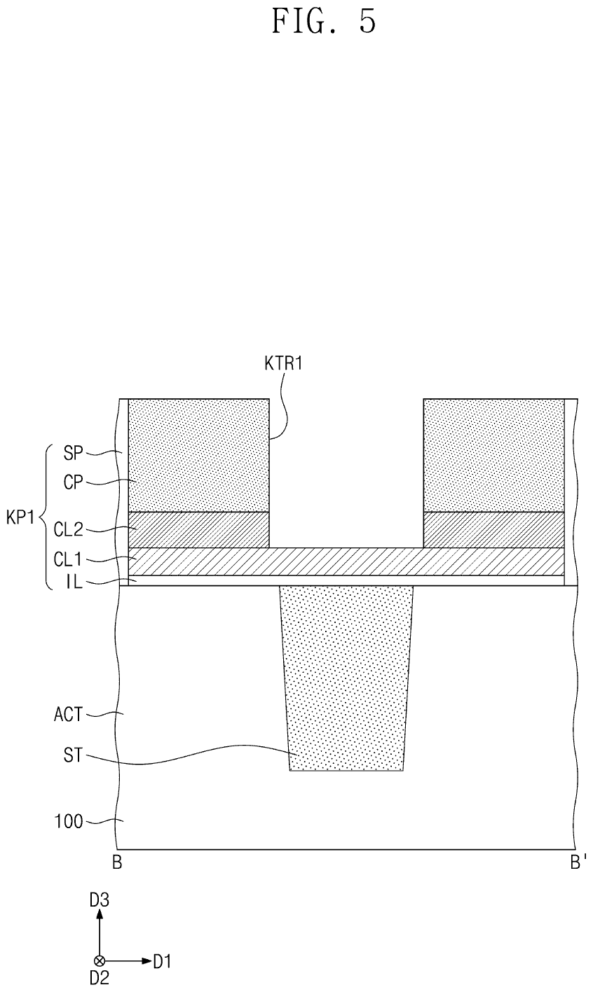

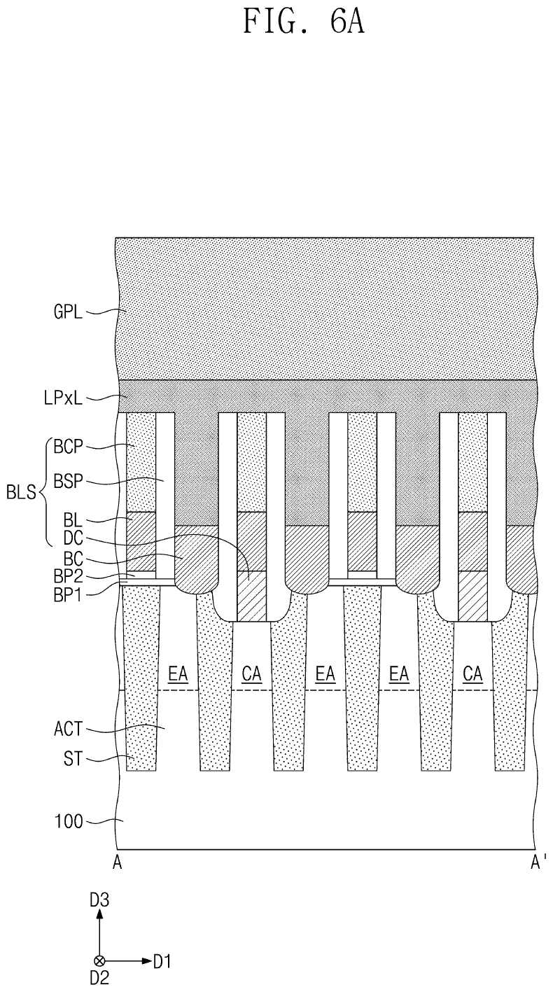

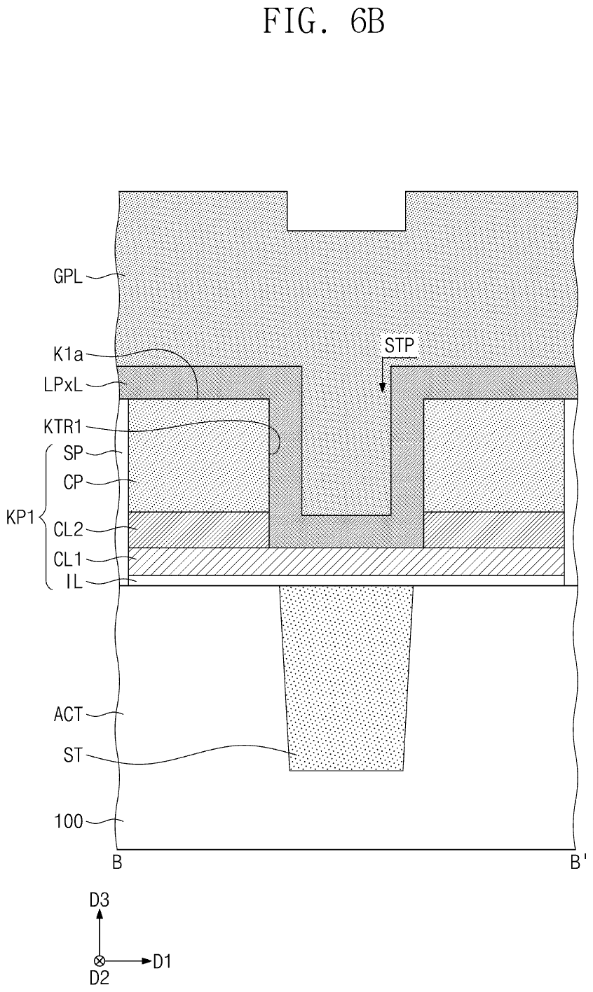

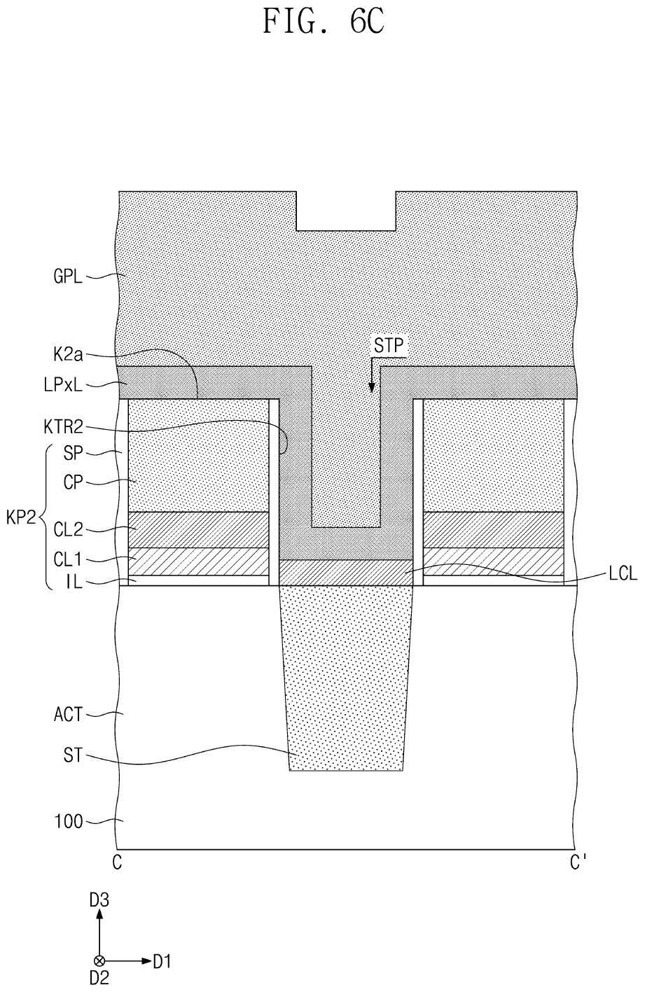

With reference to FIGS. 4A to 4C, 5, 6A to 6C, and 7A to 7C, a method of fabricating a semiconductor device according to some embodiments of the disclosure will be described. For brevity of description, an explanation of components repetitive to those discussed above will be omitted, and a difference thereof will be discussed in detail.

FIGS. 4A to 4C, 5, 6A-6C, and 7A to 7C illustrate cross-sectional views showing a method of fabricating a semiconductor device according to some embodiments of the disclosure. FIGS. 4A, 6A, and 7A illustrate cross-sectional views taken along line A-A′ of FIG. 2A. FIGS. 4B, 5, 6B, and 7B illustrate cross-sectional views taken along line B-B′ of FIG. 2B. FIGS. 4C, 6C, and 7C illustrate cross-sectional views taken along line C-C′ of FIG. 2C.

Referring to FIGS. 1, 2A, 2B, 2C, 4A, 4B, and 4C, a substrate 100 may be provided. The substrate 100 may include a cell region CER, a first alignment key region KER1, and a second alignment key region KER2. According to an embodiment, some components provided on each of the first alignment key region KER1 and the second alignment key region KER2 may be formed simultaneously with components provided on the cell region CER. In an example case in which an active pattern ACT and a device isolation pattern ST are formed on the cell region CER, an active pattern ACT and a device isolation pattern ST may be formed on each of the first alignment key region KER1 and the second alignment key region KER2. For example, the active pattern ACT and the device isolation pattern ST may be formed simultaneously on the cell region CER, the first alignment key region KER1 and the second alignment key region KER2. In an example case in which bit-line structures BLS are formed on the cell region CER, a first alignment key pattern KP1 and a second alignment key pattern KP2 may be respectively formed on the first alignment key region KER1 and the second alignment key region KER2. A second alignment key trench KTR2 may be formed when the bit-line structure BLS is formed.

According to an embodiment, a storage node contact BC may be formed between the bit-line structures BLS. In an example case in which the storage node contact BC is formed, the storage node contact BC may also be formed in a lower portion of the second alignment key trench KTR2. For example, the storage node contact BC in the lower portion of the second alignment key trench KTR2 may be referred to as the lower conductive pattern LCL.

Referring to FIGS. 1, 2B, and 5, a removal process may be performed on a portion of the first alignment key pattern KP1. Accordingly, a first alignment key trench KTR1 may be formed to penetrate at least a portion of the first alignment key pattern KP1.

Referring to FIGS. 1, 2A, 2B, 2C, 6A, 6B, and 6C, on the cell region CER, a lower landing pad layer LPxL may be formed to fill between the bit-line structures BLS. The lower landing pad layer LPxL may be provided on top surfaces of the bit-line structures BLS. For example, the lower landing pad layer LPxL may be configured to cover the top surfaces of the bit-line structures BLS. On the first alignment key region KER1, the lower landing pad layer LPxL may be formed on the first alignment key trench KTR1 and a top surface K1a of the first alignment key pattern KP1. For example, the lower landing pad layer LPxL may be formed to conformally cover the first alignment key trench KTR1 and a top surface K1a of the first alignment key pattern KP1. On the second alignment key region KER2, the lower landing pad layer LPxL may be formed on the second alignment key trench KTR2 and a top surface K2a of the second alignment key pattern KP2. For example, the lower landing pad layer LPxL may be formed to conformally cover the second alignment key trench KTR2 and a top surface K2a of the second alignment key pattern KP2. As the lower landing pad layer LPxL conformally covers the first alignment key trench KTR1 and the second alignment key trench KTR2, a step difference STP may be formed on each of the first alignment key region KER1 and the second alignment key region KER2.

According to an embodiment, on the cell region CER, a gap-fill layer GPL may be formed on a top surface of the lower landing pad layer LPxL. The gap-fill layer GPL may include a same material as the material of the first gap-fill pattern (see GP1 of FIG. 3B) discussed above. On the first alignment key region KER1, the gap-fill layer GPL may be formed to fill an unoccupied portion of the first alignment key trench KTR1 and to cover the top surface of the lower landing pad layer LPxL. On the second alignment key region KER2, the gap-fill layer GPL may be formed to fill an unoccupied portion of the second alignment key trench KTR2 and to cover the top surface of the lower landing pad layer LPxL. As the gap-fill layer GPL fills an unoccupied portion of each of the first and second alignment key trenches KTR1 and KTR2, the step difference STP may be filled which is formed on each of the first and second alignment key regions KER1 and KER2.

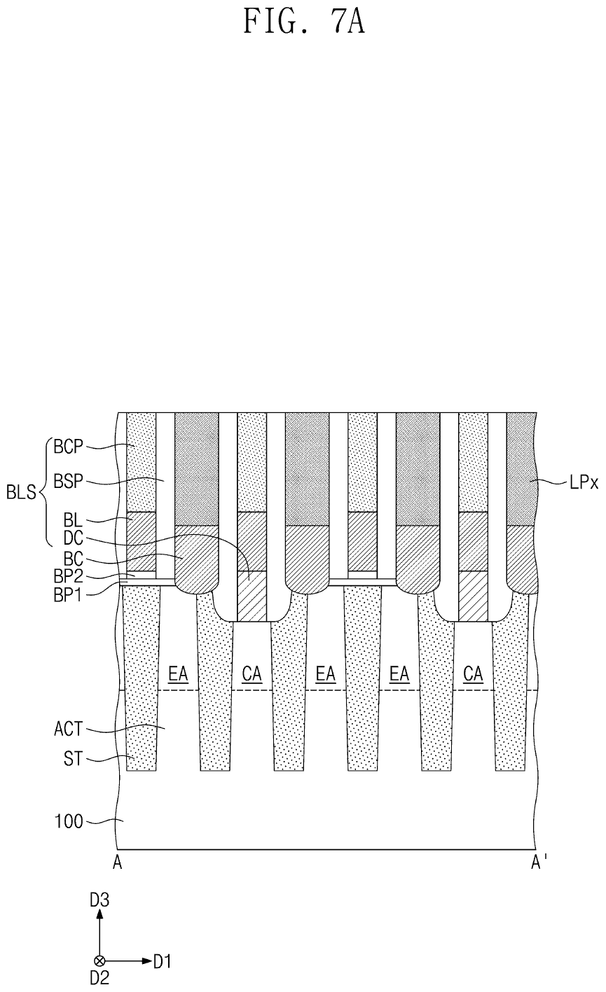

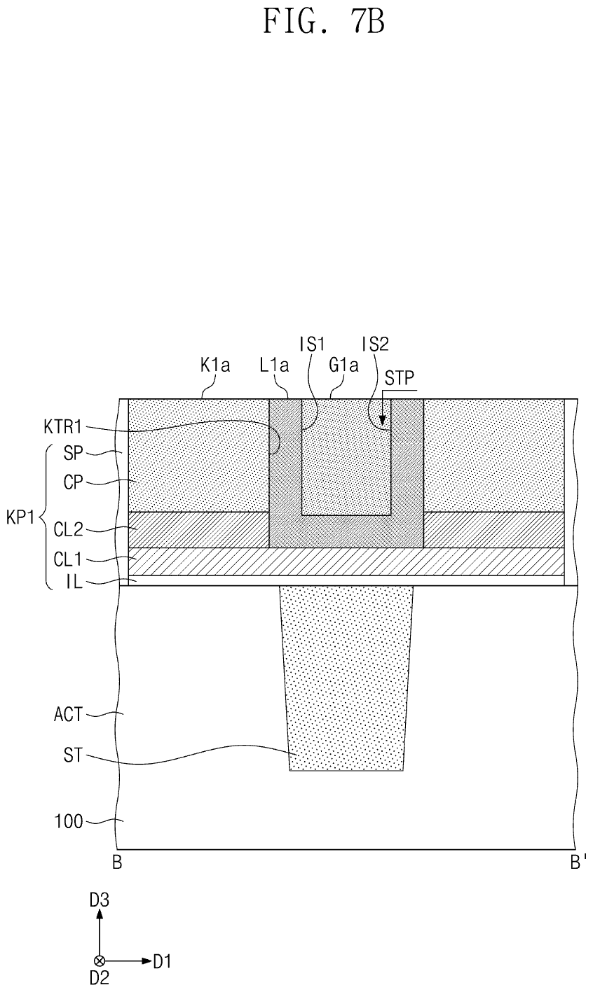

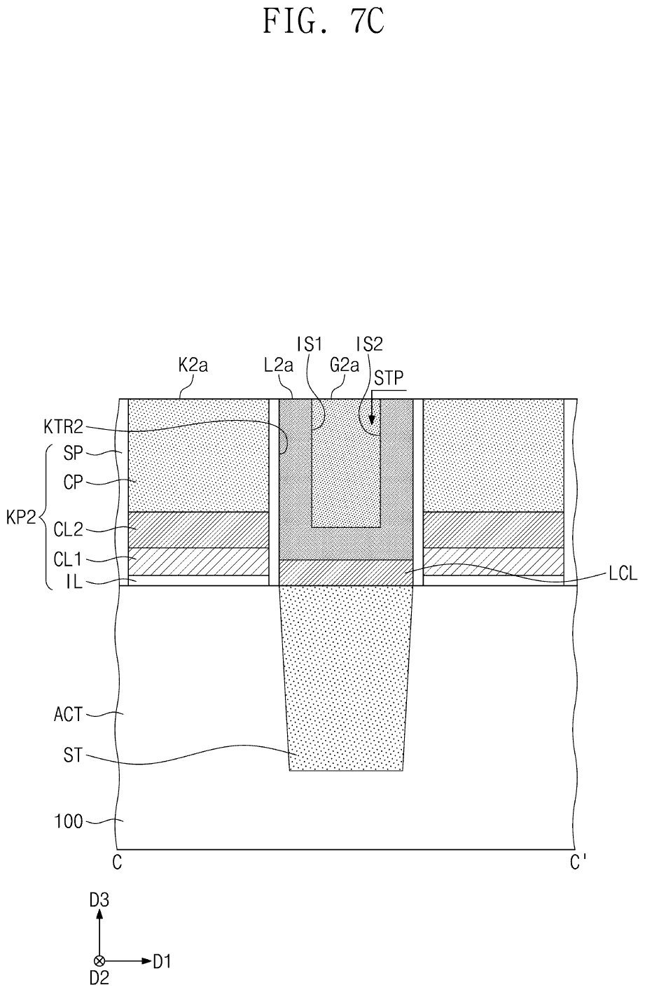

Referring to FIGS. 1, 2A, 2B, 2C, 7A, 7B, and 7C, a removal process may be performed on a portion of each of the lower landing pad layer (see LPxL of FIG. 7A) and the gap-fill layer (see GPL of FIG. 7A). For example, the removal process may include performing a CMP process (chemical mechanical planarization process or chemical mechanical polishing process). Thus, on the cell region CER, the lower landing pad layer (see LPxL of FIG. 7A) may be divided into lower landing pads LPx that are spaced apart from each other in a first direction D1. After the removal process, the lower landing pad layer (see LPxL of FIG. 7A) remaining on the first alignment key region KER1 may constitute a first liner pattern LN1. After the removal process, the lower landing pad layer (see LPxL of FIG. 7A) remaining on the second alignment key region KER2 may constitute a second liner pattern LN2. Even after the removal process is performed, the first gap-fill pattern GP1 may fill an unoccupied portion of the first alignment key trench KTR1.

On the cell region CER, the removal process may eliminate the gap-fill layer (see GPL of FIG. 7A). After the removal process, the gap-fill layer (see GPL of FIG. 7A) remaining on the first alignment key region KER1 may constitute a first gap-fill pattern GP1. After the removal process, the gap-fill layer (see GPL of FIG. 7A) remaining on the second alignment key region KER2 may constitute a second gap-fill pattern GP2. Even after the removal process is performed, the first gap-fill pattern GP1 may fill an unoccupied portion of the first alignment key trench KTR1 and the second gap-fill pattern GP2 may fill an unoccupied portion of the second alignment key trench KTR2.

The CMP process may be performed to achieve a vertical level relationship (discussed with reference to FIG. 3B) between a top surface G1a of the first gap-fill pattern GP1, a top surface L1a of the first liner pattern LN1, and a top surface K1a of the first alignment key pattern KP1. The CMP process may be performed to achieve a vertical level relationship (discussed with reference to FIG. 3C) between a top surface G2a of the second gap-fill pattern GP2, a top surface L2a of the second liner pattern LN2, and a top surface K2a of the second alignment key pattern KP2.

According to some embodiments of the disclosure, the gap-fill layer (see GPL of FIGS. 7B and 7C) may fill an unoccupied portion of each of the first alignment key trench KTR1 and the second alignment key trench KTR2. Therefore, the step difference STP which is formed on each of the first alignment key region KER1 and the second alignment key region KER2 may be filled. As a result, when the planarization process is performed, inner lateral surfaces IS1 and IS2 of each of the first and second liner patterns LN1 and LN2 may not be externally exposed and may not suffer from unnecessary damage caused by the planarization process. Accordingly, the capping pattern CP may not collapse when the planarization process is performed, which may result in a reduction in process failure of semiconductor devices and an improvement in productivity of semiconductor devices.

In addition, after the planarization process, photoresist layers may be formed on the first alignment key region KER1 and the second alignment key region KER2. In an example case in which the step difference STP is present on the first alignment key trench KTR1 and the second alignment key trench KTR2, it may not be easy to remove the photoresist layers. Thus, even after the removal process, portions of the photoresist layers may remain as particles such as defects, which may cause process failure. According some embodiments of the disclosure, even after the planarization process, the step difference STP may not be formed on any of the first alignment key trench KTR1 and the second alignment key trench KTR2, with the result that the issues above may be solved. Accordingly, process failure of semiconductor devices may be reduced to improve productivity of semiconductor devices.

Referring back to FIGS. 1, 2A, 2B, 2C, 3A, 3B, and 3C, on the cell region CER, upper landing pads LPy may be formed on the lower landing pads LPx. The upper landing pad LPy and the lower landing pad LPx may constitute a landing pad LP. A filling layer FL may be formed between the upper landing pads LPy. Data storage patterns DSP may be formed on the upper landing pads LPy.

On the first alignment key region KER1 and the second alignment key region KER2, an upper dielectric layer UIL may be formed on the top surface K1a of the first alignment key pattern KP1 and the top surface K2a of the second alignment key pattern KP2. For example, the upper dielectric layer UIL may be formed to cover the top surface K1a of the first alignment key pattern KP1 and the top surface K2a of the second alignment key pattern KP2.

According to some embodiments of the disclosure, a gap-fill layer may fill an unoccupied portion of an alignment key trench. Thus, a step difference formed on an alignment key region may be filled. When a planarization process is performed, inner lateral surfaces of a liner pattern may not be externally exposed and may not suffer from unnecessary damage caused by the planarization process. Accordingly, an alignment key pattern may not collapse when the planarization process is performed, which may result in a reduction in process failure of semiconductor devices and an improvement in productivity of semiconductor devices.

In addition, after the planarization process, photoresist layers may be formed on the alignment key region. In an example case in which a step difference is present on the alignment key trench, the photoresist layers may not be easily removed. Thus, even after the removal process, portions of the photoresist layers may remain as particles such as defects, which may cause process failure. According to some embodiments of the disclosure, even after the planarization process, no step difference may be formed on the alignment key trench and thus issues above may be solved. Accordingly, process failure of semiconductor devices may be reduced to improve productivity of semiconductor devices.

Although the inventive concepts has been described in connection with the some embodiments of the disclosure illustrated in the accompanying drawings, it will be understood by one of ordinary skill in the art that variations in form and detail may be made therein without departing from the spirit and features of the inventive concepts. The above described embodiments should thus be considered illustrative and not restrictive.

1. A method of manufacturing a semiconductor device, the method comprising:
forming a plurality of bit-line structures on a chip region of a substrate;
forming a first alignment key pattern on a scribe line region of the substrate;
forming a first alignment key trench in at least a portion of the first alignment key pattern;
forming a landing pad layer between the plurality of bit-line structures and on top surfaces of the plurality of bit-line structures;
forming a gap-fill layer on the landing pad layer and in an unoccupied portion of the first alignment key trench; and
performing a planarization process on the gap-fill layer and the landing pad layer.

2. The method of claim 1, wherein the first alignment key pattern comprises a first conductive pattern, a second conductive pattern on the first conductive pattern, and a capping pattern on the second conductive pattern,
wherein the gap-fill layer comprises a material that has an etch selectivity with respect to the capping pattern.

3. The method of claim 1, wherein the gap-fill layer comprises tungsten (W) or polycrystalline silicon (Si).

4. The method of claim 1, wherein, after the planarization process, a portion of the gap-fill layer remains as a first gap-fill pattern in the first alignment key trench.

5. The method of claim 4, wherein the unoccupied portion of the first alignment key trench is filled with the first gap-fill pattern.

6. The method of claim 4, wherein a top surface of the first gap-fill pattern is located at a vertical level substantially same as or lower than a vertical level of a top surface of the first alignment key pattern.

7. The method of claim 4, wherein, when viewed in a direction parallel to a top surface of the substrate, a width of the first gap-fill pattern decreases in a downward direction or is substantially constant.

8. The method of claim 4, wherein a top surface of the first gap-fill pattern has no step difference.

9. The method of claim 4, wherein the planarization process divides the landing pad layer into a plurality of landing pads and a first liner pattern, the plurality of landing pads provided between the plurality of bit-line structures and spaced apart from each other, and the first liner pattern provided in the first alignment key trench.

10. The method of claim 9, wherein a top surface of the first gap-fill pattern is located at a vertical level substantially same as or lower than a vertical level of a top surface of the first liner pattern.

11. The method of claim 1, further comprising forming a plurality of second alignment key patterns on the scribe line region,
wherein the landing pad layer is formed on a second alignment key trench between the plurality of second alignment key patterns, and
wherein the gap-fill layer is formed in an unoccupied portion of the second alignment key trench.

12. The method of claim 11, wherein, after the planarization process, a portion of the gap-fill layer remains as a second gap-fill pattern in the second alignment key trench.

13. The method of claim 12, wherein a top surface of the second gap-fill pattern is located at a vertical level substantially same as or lower than a vertical level of a top surface of each of the plurality of second alignment key patterns.

14. A method of fabricating a semiconductor device, the method comprising:
forming a plurality of bit-line structures on a chip region of a substrate;
forming a first alignment key pattern on a scribe line region of the substrate;
forming a first alignment key trench in at least a portion of the first alignment key pattern;
forming a landing pad layer that fills between the plurality of bit-line structures and on top surfaces of the plurality of bit-line structures;
forming a gap-fill layer on the landing pad layer and in the first alignment key trench; and
performing a planarization process on the gap-fill layer and the landing pad layer,
wherein, after the planarization process, a portion of the gap-fill layer remains in the first alignment key trench.

15. The method of claim 14, wherein a top surface of the portion of the gap-fill layer is located at a vertical level substantially same as or lower than a vertical level of a top surface of the first alignment key pattern.

16. The method of claim 14, wherein, when viewed in a direction parallel to a top surface of the substrate, a width of the portion of the gap-fill layer decreases in a downward direction or is substantially constant.

17. The method of claim 14, wherein a top surface of the portion of the gap-fill layer has no step difference.

18. The method of claim 14, further comprising forming a plurality of second alignment key patterns on the scribe line region,
wherein the landing pad layer is formed on a second alignment key trench between the plurality of second alignment key patterns, and
wherein the gap-fill layer is formed in an unoccupied portion of the second alignment key trench.

19. The method of claim 14, wherein the gap-fill layer comprises tungsten (W) or polycrystalline silicon (Si).

20. A method of fabricating a semiconductor device, the method comprising:
forming a plurality of bit-line structures on a chip region of a substrate;
forming a first alignment key pattern on a scribe line region of the substrate;
forming a plurality of storage node contacts between the plurality of bit-line structures;
forming a first alignment key trench in at least a portion of the first alignment key pattern;
forming a landing pad layer between the plurality of bit-line structures and on top surfaces of the plurality of bit-line structures;
forming a gap-fill layer on the landing pad layer and in an unoccupied portion of the first alignment key trench;
performing a planarization process on the gap-fill layer and the landing pad layer to divide the landing pad layer into a plurality of lower landing pads between the plurality of bit-line structures;
forming a plurality of upper landing pads on the plurality of lower landing pads; and
forming a plurality of data storage patterns on the plurality of upper landing pads.

21.-30. (canceled)
